(19) United States
(12) Patent Application Publication
(10) Pub. No.: US 2008/0088037 A1
(43) Pub. Date: Apr. 17, 2008

(54) Semiconductor package and method for manufacturing the same

(75) Inventors: Hyung-Jik Byun, Gyeonggi-do (KR); So-Young Jung, Daejeon Metropolitan (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/901,815

(22) Filed: Sep. 19, 2007

(30) Foreign Application Priority Data
Oct. 16, 2006 (KR) 10-2006-0100429

(51) Int. Cl. H01L 23/29; H01L 21/56

(52) U.S. Cl. 257/784; 438/118; 257/E21.502; 257/E23.119

(57) ABSTRACT

Provided are a semiconductor package and a method for manufacturing the same. The semiconductor package includes a semiconductor chip, a substrate attached to the semiconductor chip, a wire electrically connecting the semiconductor chip to the substrate, an external connection terminal electrically connecting the semiconductor chip to the outside, and an encapsulant formed of a plurality of insulators having different physical properties from each other, the encapsulant encapsulating the wire and surroundings of the wire. The method includes primarily encapsulating a window of the semiconductor package with an encapsulant having a low modulus and secondly encapsulating the window with an encapsulant having a high modulus.

### CROSS-REFERENCE TO RELATED APPLICATIONS

This U.S. non-provisional patent application claims priority under 35, U.S.C. § 119 of Korean Patent Application No. 10-2006-100429, filed in the Korean Intellectual Property Office on Oct. 16, 2006, the entire contents of which are hereby incorporated by reference.

### BACKGROUND OF THE INVENTION

The present invention described herein relates to a semiconductor package and a method for manufacturing the same, and more particularly, to a semiconductor package, which can improve its reliability, and a method for manufacturing the same.

In a semiconductor package, a semiconductor chip is attached to a substrate. The semiconductor chip is electrically connected to the substrate through bonding wires. An insulator protects the bonding wires and the semiconductor chip from contamination or moisture. The semiconductor package further includes a solder ball array attached to the substrate. Solder balls serve as input/output terminals. Pads are formed at an edge or center portion of the semiconductor chip to electrically connect the semiconductor chip to the bonding wires. A structure in which pads are formed at the center portion of the semiconductor chip is referred to as a center pad structure, and a structure in which pads are formed at the edges of the semiconductor chip is referred to as an edge pad structure. In the semiconductor package, the bonding wires in the center pad structure are shorter than those in the edge pad structure. Therefore, in the center pad structure, the bonding wires are less damaged, the failure rate of the bonding wires is reduced, and the signal delay is reduced.

FIG. 1 is a cross-sectional view of a typical semiconductor package having a center pad structure. Referring to FIG. 1, the typical semiconductor package 1 having the center pad structure includes a substrate 20 attached to a semiconductor chip 10 through an adhesive 14. An opened window 26 is formed at a center portion of the substrate 20. Pads 12 are disposed on a center portion of the semiconductor chip 10 and exposed through the window 26. In addition, pads 22 are disposed on the substrate 20 and protected by an insulating layer 27. The semiconductor package 1 may further include an insulating layer 28 and pads (not shown) protected by the insulating layer 28 on the substrate 20. The pads 12 on the semiconductor chip 10 are electrically connected to the pads 22 on the substrate 20 through bonding wires 30 in the window 26. Solder balls 40 serving as external connection terminals are attached to the substrate 20. The window 26 is filled with an insulator 32 serving as an encapsulant. The insulator 32 protects the pads 12 and 22 and the bonding wires 30 from moisture or contaminants.

The electrical properties and reliability of the semiconductor package 1 depend on the insulator 32 filing the window 26. For example, when a material having a low modulus is selected as the insulator 32, the material expands and the bonding wires 30 are under tensile stress during a temperature cycle (TC) and a high temperature storage (HTS), which are related to the reliability of the semiconductor package 1. As a result, the bonding wires 30 are cut off.

To overcome these limitations, a material having a high modulus may be selected as the insulator 32. In this case, however, the substrate 20 is bent during the TC and the HTS. As a result, it is difficult to stack semiconductor packages. In addition, the interface between the substrate 20 and the insulator 32 may be cracked by the difference of their coefficients of thermal expansion (CTE).

### SUMMARY OF THE INVENTION

The present invention provides a semiconductor package, which can improve reliability, and a method for manufacturing the same.

The present invention also provides a semiconductor package and a method for manufacturing the same, in which a window is filled with insulators having different moduli, thereby overcoming the limitations caused by the expansion of the insulator and the limitations of reliability related to heat.

According to a first aspect, the present invention is directed to a semiconductor package including: a semiconductor chip; a substrate attached to the semiconductor chip; a wire electrically connecting the semiconductor chip to the substrate; an external connection terminal electrically connecting the semiconductor chip to the outside; and an encapsulant encapsulating the wire and surroundings of the wire, the encapsulant being formed of a plurality of insulators having different physical properties from each other.

In some embodiments, the physical properties are moduli of the insulators.

In other embodiments, the insulators include a first insulator and a second insulator covering the first insulator, the first insulator has a modulus less than that of the second insulator, and the second insulator has a modulus greater than that of the first insulator.

In still other embodiments, the insulators further include a third insulator formed between the first and second insulators, and the third insulator has a modulus greater than that of the first insulator and less than that of the second insulator.

According to another aspect, the present invention is directed to a semiconductor package including: a semiconductor chip; a substrate attached to the semiconductor chip and including a window exposing a portion of the semiconductor chip; a wire electrically connecting the semiconductor chip to the substrate through the window; an external connection terminal attached to the substrate, for electrically connecting the semiconductor chip to the outside; and an encapsulant formed of a plurality of insulators having different moduli from each other, for encapsulating the window.

In some embodiments, the insulators include: a first insulator covering a central portion of the semiconductor chip exposed through the window and having a first modulus; and a second insulator covering the first insulator and having a second modulus greater than the first modulus.

In other embodiments, the first insulator includes a thermosetting resin having a modulus ranging from 3 MPa to 300 MPa, and the second insulator includes a thermosetting resin having a modulus ranging from 5 GPa to 10 GPa. in one embodiment, the thermosetting resin of the first insulator includes a silicon resin, and the thermosetting resin of the second insulator includes an epoxy resin.

In still other embodiments, the insulators further include a third insulator disposed between the first and second insulators and having a third modulus greater than the first modulus and less than the second modulus.

In even other embodiments, the first insulator occupies 50% through 70% of the total volume of the window.

In yet other embodiments, the semiconductor chip includes an active surface to which the substrate is attached and an inactive surface opposite to the active surface, the semiconductor package further comprising a first pad electrically connected to the wire at a central portion of the active surface.

In further embodiments, the substrate includes a bottom surface attached to the active surface of the semiconductor chip and a top surface opposite to the bottom surface, the semiconductor package further comprising a second pad electrically connected to the first pad using the wire on the top surface.

In still further embodiments, the external connection terminal is attached to the top surface of the substrate so that the external connection terminal is disposed in an outside of the semiconductor chip.

In even further embodiments, the bottom surface of the substrate includes a third pad disposed at an outside of the semiconductor chip.

According to another aspect, the present invention is directed to a method of manufacturing a semiconductor package, the method including: attaching a substrate including a window to the semiconductor chip; electrically connecting the semiconductor chip to the substrate through the window; primarily encapsulating a portion of the window with a first insulator having a first modulus; secondarily encapsulating the first insulator with a second insulator having a second modulus greater than the first modulus; and attaching an external connection terminal to the substrate.

In some embodiments, the attaching of the substrate including the window to the semiconductor chip includes interposing an adhesive between the active surface of the semiconductor chip and the bottom surface of the substrate to adhere an active surface of the semiconductor chip to a bottom surface of the substrate so that a portion of the active surface of the semiconductor chip is exposed through the window.

In other embodiments, the electrically connecting of the semiconductor chip to the substrate includes electrically connecting the portion of the active surface of the semiconductor chip exposed through the window to a top surface of the substrate, using a conductive wire passing through the window.

In still other embodiments, the primary encapsulating includes: selecting a first thermosetting resin as the first insulator; forming the first thermosetting resin on the active surface of the semiconductor chip exposed through the window; and curing the first thermosetting resin.

In even other embodiments, the applying and curing of the first thermosetting resin includes selecting a silicon resin as the first thermosetting resin and applying the silicon resin so as to fill 50% through 70% of the total volume of the window with the silicon resin.

In yet other embodiments, the secondary encapsulating includes: selecting a second thermosetting resin as the second insulator; forming the second thermosetting resin on the silicon resin; and curing the second thermosetting resin.

In further embodiments, the applying and curing of the second thermosetting resin includes selecting an epoxy resin as the second thermosetting resin and applying the epoxy resin on the first thermosetting resin and curing the epoxy resin.

In still further embodiments, the attaching of the external connection terminal includes attaching the external connection terminal to a top surface of the substrate so that the external connection terminal is disposed in the outside of the semiconductor chip.

In even further embodiments, the method further includes encapsulating the first insulator with a third insulator having a third modulus greater than the first modulus and less than the second modulus, after the primary encapsulating and before the second encapsulating.

According to the present invention, a window of a semiconductor package having a center pad structure is primarily encapsulated with an encapsulant having a low modulus, and then, is secondly encapsulated with an encapsulant having a high modulus. Therefore, when the semiconductor package is manufactured, the semiconductor package operates, and reliability tests are performed, the encapsulant having a high modulus prevents the expansion of the encapsulant having a low modulus.

### BRIEF DESCRIPTION OF THE FIGURES

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a cross-sectional view of a typical semiconductor package.

FIGS. 2 through 5 are cross-sectional views illustrating a method for manufacturing a semiconductor package according to an embodiment of the present invention.

FIG. 6 is a cross-sectional view of a dual stack package using a semiconductor package according to an embodiment of the present invention.

FIG. 7 is a cross-sectional view of a semiconductor package according to another embodiment of the present invention.

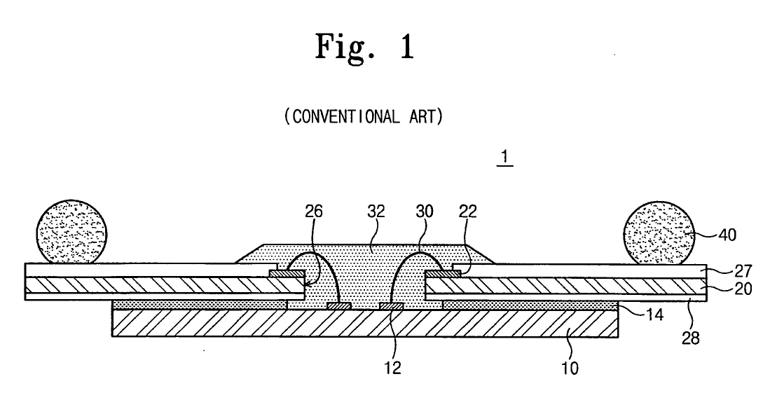

### DETAILED DESCRIPTION OF PREFERRED EMBODIMENTS

Hereinafter, a semiconductor package and a method for manufacturing the same will be described in detail with reference to the accompanying drawings.

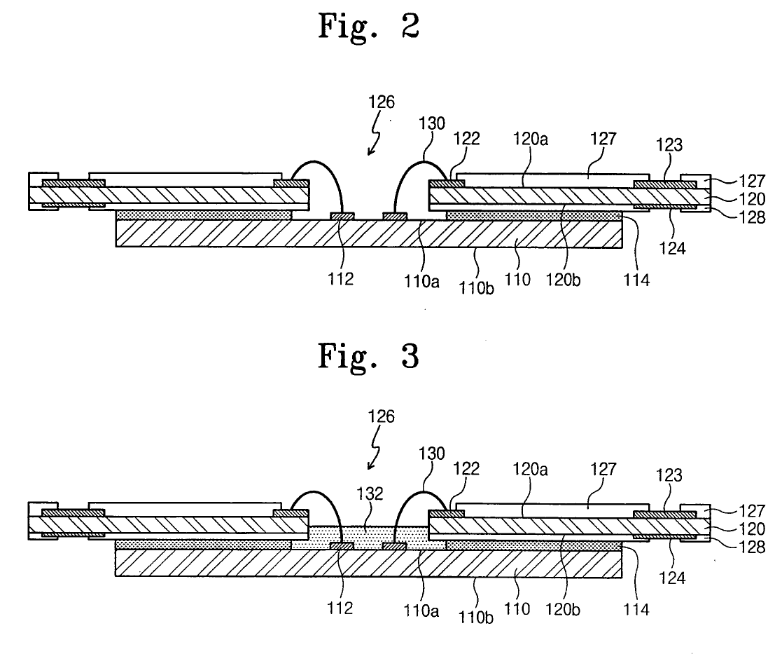

FIGS. 2 through 5 are cross-sectional views illustrating a method for manufacturing a semiconductor package according to an embodiment of the present invention.

Referring to FIG. 2, a semiconductor chip 110 and a substrate 120 are prepared. The semiconductor chip 110 has a first surface 110a and a second surface 110b opposite to the first surface 110a. The first surface 110a of the semiconductor chip 110 is an active surface on which a plurality of circuit patterns and a plurality of pads 112 are formed. The second surface 110b is an inactive surface. A substrate 120 may be, e.g., a printed circuit board (PCB). The substrate 120 has a bottom surface 120b and a top surface 120a. The bottom surface 120b of the substrate 120 contacts the active surface 110a of the semiconductor chip 110. A window 126 is formed at the center portion of the substrate 120, such that it passes through the substrate 120 in a vertical direction. A plurality of pads 122 and 123 and an insulating layer 127 are disposed on the top surface 120a of the substrate 120. The insulating layer 127 protects the pads 122 and 123. The substrate 120 may have a two-layer structure in which a plurality of pads 124 and an insulating layer 128 protecting the pads 124 are further disposed on the bottom surface 120b of the substrate 120.

The substrate 120 is mounted on the semiconductor chip 110 using an adhesive 114, such that the active surface 110a of the semiconductor chip 110 faces the bottom surface 120b of the substrate 120. This structure is called a BOC (board on chip) structure. When the substrate 120 is mounted on the semiconductor chip 110, the pads 112 on the active surface 110a of the semiconductor chip 110 are exposed through the window 126. When the insulating layer 128 is further formed on the bottom surface 120b of the substrate 120, the substrate 120 is mounted on the semiconductor chip 110 by attaching the active surface 110a of the semiconductor chip 110 to the insulating layer 128 using the adhesive 114. After the substrate 120 is mounted on the semiconductor chip 110, a plurality of bonding wires 130 are formed through the window 126 using a well-known process. Both ends of the bonding wire 130 are electrically connected to the pad 112 of the semiconductor chip 110 and the pad 122 of the substrate 120, respectively. Therefore, the semiconductor chip 110 is electrically connected to the substrate 120. The bonding wire 130 is formed of a conductive material, e.g., gold (Au).

Referring to FIG. 3, the window 126 is primarily encapsulated with an insulator in order to protect the bonding wire 130 and the pads 112 and 122 from moisture and contaminants. A first insulator 132 is formed on the active surface 110a of the semiconductor chip 110 exposed through the window 126 and then cured to primarily encapsulate a portion of the window 126. One of the thermosetting resins may be selected as the first insulator 132. The substrate 120 may be bent when a material having a relatively high modulus (i.e., Young's modulus) is selected as the first insulator 132. Also, cracks may occur at the interface between the substrate 120 and the first insulator 132 due to the difference of their coefficients of thermal expansion (CTE). This phenomenon may also occur at the interface between the semiconductor chip 110 and the first insulator 132. Therefore, it is preferable that a material having a relatively low modulus may be selected as the thermosetting resin for the first insulator 132.

For example, a silicon resin having a modulus approximately ranging from 3 Mpa to 300 MPa may be selected as the first insulator 132. As described below, about more than 50%, e.g., about ranging from 50% to about 70% of the total volume of the window 126 may be filled with the first insulator 132. A portion of the bonding wire 130 may be exposed through the first insulating layer 132. The first insulator 132 may be formed using a well-known method such as lid sealing process, a dispensing process, or a printing process.

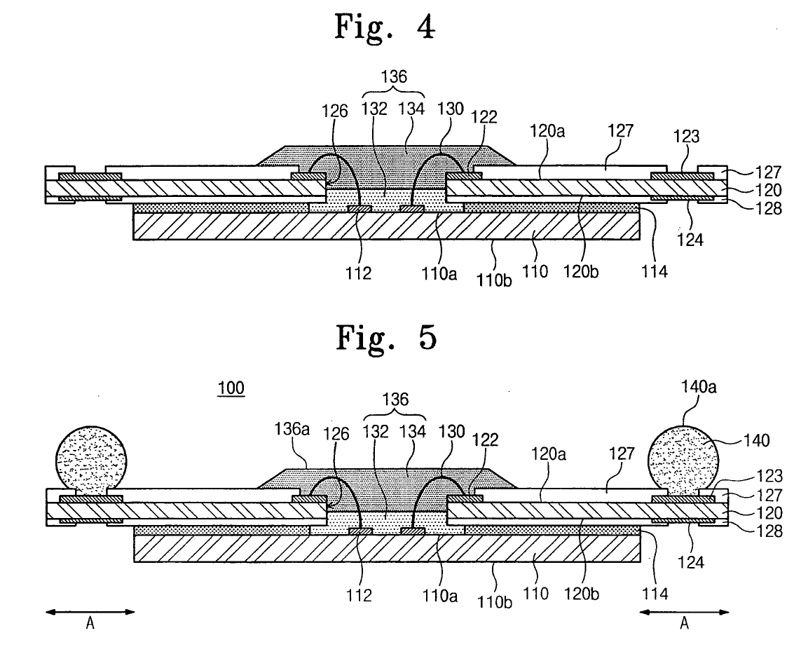

Referring to FIG. 4, a second insulator 134 is formed to cover the first insulator 132 and the pad 122 in order to completely encapsulate the window 126 and then is cured. The portion of the bonding wire 130 exposed through the first insulating layer 132 is completely encapsulated by the second insulator 134. A portion of the second insulator 134 may be overlapped with a portion of the substrate 120. One of the thermosetting resins having different physical properties from that of the first insulator 132 may be selected as the second insulator 134. In case where a resin having a relatively low modulus such as silicon is selected as the first insulator 132, the first insulator 132 may be expanded while a temperature cycle (TC) and a high temperature storage (HTS) are performed on the first insulator 132. The TC and HTS are related to the reliability of the semiconductor package 100. When the first insulator 132 is expanded, the bonding wire 130 is under tensile stress. As a result, the bonding wire 130 may be cut off. Therefore, it is preferable that the second insulator 134 can prevent the expansion of the first insulator 132. Preferably, a material having a modulus greater than that of the first insulator 132 is selected as the second insulator 134.

For example, an epoxy resin having a modulus ranging from approximately 5 GPa to approximately 10 GPa may be selected as the second insulator 134. The second insulator 134 may be formed using a well-known method such as the lid sealing process, a dispensing process, and a printing process. As described above, an encapsulant 136 protecting the pads 112 and 122 and the bonding wire 130 is formed through the forming and curing of the first insulator 132 having a low modulus and the second insulator 134 having a high modulus.

If the first insulator 132 occupies too small space of the window 126, the second insulator 134 should occupy more space of the window 126. As a result, the semiconductor chip 110 or substrate 120 may be bent, or cracks may occur at the interface between the semiconductor chip 110 and the encapsulant 136 and/or the interface between the substrate 120 and the encapsulant 136. On the other hand, if the first insulator 132 occupies too much space of the window 126, the second insulator 134 cannot sufficiently prevent the expansion of the first insulator 132. Therefore, it is preferable that more than about 50%, e.g., about 50% through about 70% of the total volume of the window 126 is filled with the first insulator 132.

Referring to FIG. 5, a plurality of external connection terminals, e.g., a plurality of solder balls 140, are attached to the substrate 120 so that the solder balls 140 are electrically connected to the pads 123 to form the semiconductor package 100, that is, a mono stack package (MSP). The solder ball 140 is disposed in an outside region A of the semiconductor chip 110. The semiconductor package 100 according to an embodiment of the present invention has a Fan Out structure in which the solder ball 140 is disposed in the outside region A of the semiconductor chip 110. A top end 140a of the solder ball 140 is greater than a top end 136a of the encapsulant 136. Hence, a plurality of semiconductor packages 100 can be easily stacked. In addition, the encapsulant 136 is prevented from contacting another substrate when the semiconductor package 100 is mounted to another substrate.

The semiconductor package 100 formed through the series of processes described above has a center pad structure. In the center pad structure, the pad 112 is formed on the central portion of the semiconductor chip 110, and the window 126 is formed in the central portion of the substrate 120, and then, the semiconductor chip 110 is electrically connected to the substrate 120 through the window 126 using the bonding wire 130. The encapsulant 136 comprises the first insulator 132 having a low modulus and the second insulator 134 having a high modulus. The second insulator 134 prevents the expansion of the first insulator 132.

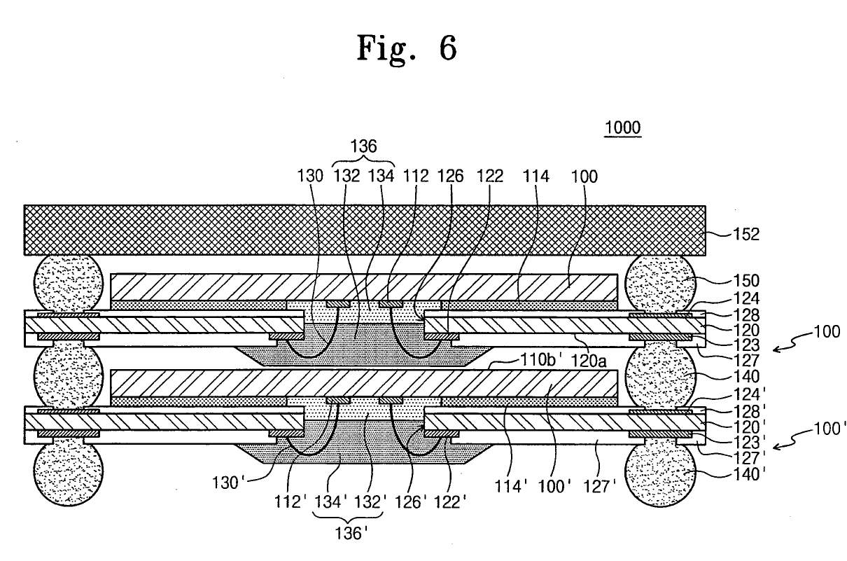

FIG. 6 is a cross-sectional view of a dual stack package (DSP) 1000 in which semiconductor packages are double-stacked, according to an embodiment of the present invention.

Referring to FIG. 6, the DSP 1000 includes two semiconductor packages 100 and 100′ vertically stacked. The semiconductor package 100 (hereinafter, referred to as a first semiconductor package) and the semiconductor package 100′ (hereinafter, referred to as a second semiconductor package) are formed through the series of processes described above. The first and second semiconductor packages 100 and 100′ are stacked with an upper surface 120a of a substrate 120 of the first semiconductor package 100 facing a bottom surface 110b′ of a semiconductor chip 110′ of the second semiconductor package 100′. A solder ball 140 of the first semiconductor package 100 is electrically connected to a pad 124′ of the second semiconductor package 100′ to electrically connect the first semiconductor package 100 to the second semiconductor package 100′. A solder ball 140′ of the second semiconductor package 100′ is electrically connected to an external substrate (not shown).

An encapsulant 136 of the first semiconductor package 100 includes a first insulator 132 having a low modulus and a second insulator 134 having a high modulus. An encapsulant 136′ of the second semiconductor package 100′ also includes a first insulator 132′ having a low modulus and a second insulator 134′ having a high modulus. As described above, since substrates 120 and 120′ or semiconductor chips 110 and 110′ are not bent. No cracks may occur at the interfaces between the semiconductor chips 110 and 110′ and the encapsulants 136 and 136′ and/or the interfaces between the substrates 120 and 120′ and the encapsulants 136 and 136′. The stacking fault of the first and second semiconductor packages 100 and 100′ can be avoided or minimized.

To protect the DSP 1000, a cap 152 may be further attached to a bottom surface 120b of the substrate 120 of the first semiconductor package 100 using a solder ball 150. The cap 152 may be an insulator and serves as a protective layer.

### Modified Embodiment

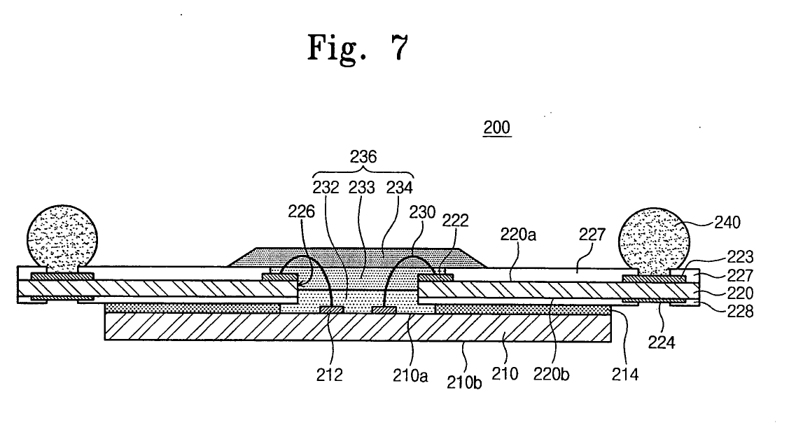

FIG. 7 is a cross-sectional view of a semiconductor package according to a modified embodiment of the present invention.

Referring to FIG. 7, the semiconductor package 200 is formed through the same as the method for manufacturing the semiconductor package 100 as described above. However, in this embodiment, an encapsulant 236 has a triple stacked insulator structure by forming and curing a first insulator 232, forming and curing a second insulator 233, and forming and curing a third insulator 234. The first insulator 232 may be formed of a thermosetting resin having a modulus less than those of the second and third insulators 233 and 234. The third insulator 234 may be formed of a thermosetting resin having a modulus greater than those of the first and second insulators 232 and 233. The second insulator 233 may be formed of a thermosetting resin having a modulus greater than that of the first insulator 232 and less than that of the third insulators 234. For example, the first insulator 232 may be a silicon resin having a modulus ranging from approximately 3 MPa to approximately 300 MPa. The third insulator 234 may be a silicon resin having a modulus ranging from approximately 5 GPa to approximately 10 GPa. The second insulator 233 may be a thermosetting resin such as a silicon resin, an epoxy resin, a polyimide resin, and a bismaleimide triazine (BT) resin, and an FR4 resin, which has a modulus higher than that of the first insulator 232 and lower than that of the third insulators 234.

Although the semiconductor chip having the center pad structure in which the central portion of the semiconductor chip is exposed through the window has been described above, the present invention can be applied to any type of semiconductor package with an encapsulant. That is, an encapsulant of a semiconductor package can be formed of various insulators having different moduli from each other.

As described above, according to the present invention, the window of the semiconductor package is primarily encapsulated with the encapsulant having a low modulus, and then, secondly encapsulated with the encapsulant having a high modulus. Therefore, when the semiconductor package is manufactured or the semiconductor package operates and reliability tests are performed, the encapsulant having a high modulus prevents the expansion of the encapsulant having a low modulus, and thus, the reliability of the semiconductor package can be improved.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor package comprising:
a semiconductor chip;
a substrate attached to the semiconductor chip;
a wire electrically connecting the semiconductor chip to the substrate;
an external connection terminal electrically connecting the semiconductor chip to the outside; and
an encapsulant encapsulating the wire and surroundings of the wire, the encapsulant being formed of a plurality of insulators having different physical properties from each other.

2. The semiconductor package of claim 1, wherein the physical properties are moduli of the insulators.

3. The semiconductor package of claim 2, wherein the insulators comprise a first insulator and a second insulator covering the first insulator, and the first insulator has a modulus less than that of the second insulator.

4. The semiconductor package of claim 3, wherein the insulators further comprises a third insulator interposed between the first and second insulators and having a modulus greater than that of the first insulator and less than that of the second insulator.

5. A semiconductor package comprising:
a semiconductor chip;
a substrate attached to the semiconductor chip and including a window exposing a portion of the semiconductor chip;
a wire electrically connecting the semiconductor chip to the substrate through the window;
an external connection terminal attached to the substrate to electrically connect the semiconductor chip to the outside; and
an encapsulant including a plurality of insulators with different moduli from each other, the encapsulant encapsulating the window.

6. The semiconductor package of claim 5, wherein the insulators comprise:
a first insulator covering a central portion of the semiconductor chip exposed through the window and having a first modulus; and
a second insulator covering the first insulator and having a second modulus greater than the first modulus.

7. The semiconductor package of claim 6, wherein the first insulator comprises a thermosetting resin having a modulus ranging from 3 MPa to 300 MPa, and the second insulator comprises a thermosetting resin having a modulus ranging from 5 GPa to 10 GPa.

8. The semiconductor package of claim 7, wherein the thermosetting resin of the first insulator comprises a silicon resin, and the thermosetting resin of the second insulator comprises an epoxy resin.

9. The semiconductor package of claim 6, wherein the insulators further comprise a third insulator interposed between the first and second insulators and having a third modulus greater than the first modulus and less than the second modulus.

10. The semiconductor package of claim 5, wherein the first insulator occupies 50% through 70% of the total volume of the window.

11. The semiconductor package of claim 5, wherein the semiconductor chip comprises an active surface to which the substrate is attached and an inactive surface opposite to the active surface, a central portion of the active surface comprising a first pad electrically connected to the wire.

12. The semiconductor package of claim 11, wherein the substrate comprises a bottom surface attached to the active surface of the semiconductor chip and a top surface opposite to the bottom surface, the top surface comprising a second pad electrically connected to the first pad.

13. The semiconductor package of claim 12, wherein the external connection terminal is attached to the top surface of the substrate so that the external connection terminal is disposed in an outside of the semiconductor chip.

14. The semiconductor package of claim 12, wherein the bottom surface of the substrate comprises a third pad disposed in an outside of the semiconductor chip.

15. A method for manufacturing a semiconductor package, the method comprising:
attaching a substrate including a window to the semiconductor chip;
electrically connecting the semiconductor chip to the substrate through the window;
primarily encapsulating a portion of the window with a first insulator having a first modulus;
secondarily encapsulating the first insulator with a second insulator having a second modulus greater than the first modulus; and
attaching an external connection terminal to the substrate.

16. The method of claim 15, wherein the attaching of the substrate including the window to the semiconductor chip comprises;
interposing an adhesive between the active surface of the semiconductor chip and the bottom surface of the substrate to adhere an active surface of the semiconductor chip to a bottom surface of the substrate so that a portion of the active surface of the semiconductor chip is exposed through the window.

17. The method of claim 16, wherein the electrically connecting of the semiconductor chip to the substrate comprises;
electrically connecting the portion of the active surface of the semiconductor chip exposed through the window to a top surface of the substrate using a conductive wire passing through the window.

18. The method of claim 16, wherein the primary encapsulating comprises:
selecting a silicon resin as the first insulator;
forming the silicon resin on the active surface of the semiconductor chip exposed through the window, so as to fill 50% through 70% of the total volume of the window with the silicon resin; and
curing the silicon resin.

19. The method of claim 18, wherein the secondary encapsulating comprises:
selecting an epoxy resin as the second insulator;
forming the epoxy resin on the silicon resin; and
curing the epoxy resin.

20. The method of claim 15, wherein the attaching of the external connection terminal comprises;
attaching the external connection terminal to a top surface of the substrate so that the external connection terminal is disposed in the outside of the semiconductor chip.

21. The method of claim 15, further comprising encapsulating the first insulator with a third insulator having a third modulus greater than the first modulus and less than the second modulus, after the primary encapsulating and before the second encapsulating.
